(19) United States
(12) Patent Application Publication
(10) Pub. No.: US 2015/0221557 A1
(43) Pub. Date: Aug. 6, 2015

(54) WIRING STRUCTURES AND METHODS OF FORMING THE SAME

(71) Applicant: Samsung Electronics Co., Ltd., Suwon-si (KR)

(72) Inventors: Cheon-Bae Kim, Hwaseong-si (KR); Jung-Hoon Han, Hwaseong-si (KR); Byung-Hoon Cho, Hwaseong-si (KR)

(21) Appl. No.: 14/452,665

(22) Filed: Aug. 6, 2014

(30) Foreign Application Priority Data
Feb. 5, 2014 (KR) 10-2014-0013122

(51) Int. Cl. H01L 21/8234; H01L 23/532; H01L 21/311; H01L 21/3213; H01L 21/768; H01L 21/02

(52) U.S. Cl. CPC H01L 21/823475; H01L 21/76802; H01L 21/76897; H01L 21/76846; H01L 21/02167; H01L 21/31116; H01L 21/32135; H01L 23/53266

(57) ABSTRACT

In a method of forming a wiring structure, a carbon-containing layer may be formed on a substrate. A conductive layer may be formed on the carbon-containing layer, and the conductive layer may be formed to include a metal. The conductive layer and an upper portion of the carbon-containing layer may be etched to form a wiring and a carbon-containing layer pattern, respectively.

### CROSS-REFERENCE TO RELATED APPLICATION

This application claims priority under 35 USC §119 to Korean Patent Application No. 10-2014-0013122, filed on Feb. 5, 2014 in the Korean Intellectual Property Office (KIPO), the contents of which are herein incorporated by reference in their entirety.

### BACKGROUND

Example embodiments relate to wiring structures and methods of forming the same. More particularly, example embodiments relate to wiring structures including a metal and methods of forming the same.

A wiring of a semiconductor device may be formed by forming a metal layer containing a metal, e.g., aluminum and etching the metal layer through a dry etching process. When the metal layer has a relatively thick thickness, a lower sidewall of the metal layer may be over-etched so that the wiring may be formed with a poor resistance property.

### SUMMARY

Example embodiments provide a wiring structure having superior characteristics.

Example embodiments provide a method of forming a wiring structure having superior characteristics.

According to example embodiments, there is provided a method of forming a wiring structure. A carbon-containing layer may be formed on a substrate. A conductive layer may be formed on the carbon-containing layer, and the conductive layer may be formed to include a metal. The conductive layer and an upper portion of the carbon-containing layer may be etched to form a wiring and a carbon-containing layer pattern, respectively.

In example embodiments, when the conductive layer and the upper portion of the carbon-containing layer are etched, a polymer may be formed on a lower sidewall of the wiring from carbon in the carbon-containing layer.

In example embodiments, the carbon-containing layer may include silicon carbide or silicon carbonitride.

In example embodiments, prior to forming the carbon-containing layer, an insulating interlayer may be formed on the substrate, and a contact plug may be formed through the carbon-containing layer and the insulating interlayer.

In example embodiments, the conductive layer may be formed on the carbon-containing layer and the contact plug, and the wiring may be formed on the contact plug.

In example embodiments, prior to forming the conductive layer, a barrier layer may be further formed on the carbon-containing layer.

In example embodiments, the conductive layer may be formed using aluminum

In example embodiments, the conductive layer and the upper portion of the carbon-containing layer may be etched by using a dry etching process.

According to other example embodiments, there is provided a wiring structure. The wiring structure includes a contact plug, a carbon-containing layer pattern and a wiring. The contact plug may be formed on a substrate. The carbon-containing layer pattern may surround at least a portion of a sidewall of the contact plug. The wiring may be formed on the contact plug and the carbon-containing layer pattern, and the wiring may be electrically connected to the contact plug.

In example embodiments, the carbon-containing layer pattern may have a flat upper surface under the wiring, and a recess may be formed on an upper surface of the carbon-containing layer pattern adjacent to the wiring.

In example embodiments, a barrier layer pattern may be further formed between the wiring and the contact plug and the carbon-containing layer pattern.

In example embodiments, an insulating interlayer may be further formed between the substrate and the carbon-containing layer pattern, and the insulating interlayer may surround a lower sidewall of the contact plug.

In example embodiments, the wiring may have a smooth sidewall profile.

In example embodiments, the wiring may include aluminum.

In example embodiments, the carbon-containing layer pattern may include silicon carbide or silicon carbonitride.

According to other example embodiments, there is provided a method of manufacturing a semiconductor device. A gate structure may be formed on a substrate. An impurity region may be formed at an upper portion of the substrate adjacent to the gate structure. An insulating interlayer may be formed on the substrate to cover the gate structure. A carbon-containing layer may be formed on the insulating interlayer. A contact plug may be formed through the carbon-containing layer and the insulating interlayer, and the contact plug may be electrically connected to the impurity region. A conductive layer may be formed on the contact plug and the carbon-containing layer, and the conductive layer may be formed to include a metal. The conductive layer and an upper portion of the carbon-containing layer may be etched to form a wiring and a carbon-containing layer pattern, respectively.

In example embodiments, when the conductive layer and the upper portion of the carbon-containing layer are etched, a polymer may be formed on a lower sidewall of the wiring from carbon in the carbon-containing layer.

In example embodiments, the carbon-containing layer may include silicon carbide or silicon carbonitride.

In example embodiments, the wiring may be formed on the contact plug.

In example embodiments, prior to forming the conductive layer, a barrier layer may be further formed on the carbon-containing layer.

According to example embodiments, there is provided a wiring structure which may not be horizontally etched.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIGS. 1 to 5 are cross-sectional views illustrating stages of a method of forming a wiring structure in accordance with example embodiments;

FIG. 6 is a cross-sectional view illustrating a stage of a method of forming a wiring structure in accordance with Comparative Example; and

FIGS. 7 to 16 are cross-sectional views illustrating stages of a method of manufacturing a semiconductor device including a wiring structure in accordance with example embodiments.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

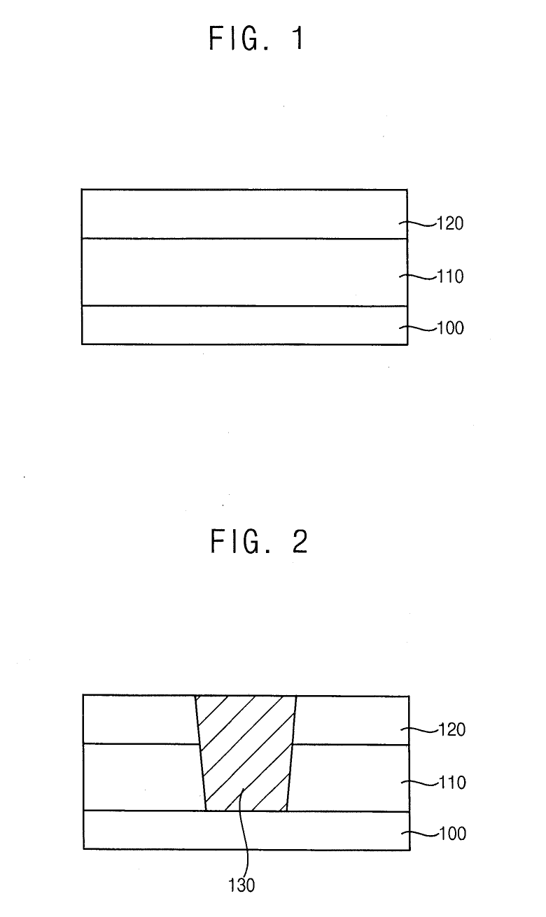

FIGS. 1 to 5 are cross-sectional views illustrating stages of a method of forming a wiring structure in accordance with example embodiments, and FIG. 6 is a cross-sectional view illustrating a stage of a method of forming a wiring structure in accordance with Comparative Example.

Referring to FIG. 1, a first insulating interlayer 110 and a carbon-containing layer 120 may be sequentially formed on a substrate 100.

The substrate 100 may comprise a silicon substrate, a germanium substrate, a silicon-germanium substrate, a silicon-on-insulator (SOI) substrate, a germanium-on-insulator (GOI) substrate, etc.

The first insulating interlayer 110 may be formed of an oxide, e.g., phospho silicate glass (PSG), boro phospho silicate glass (BPSG), undoped silicate glass (USG), tetra ethyl ortho silicate (TEOS), a HDP-CVD oxide, etc. by, using e.g., a chemical vapor deposition (CVD) process, a plasma enhanced chemical vapor deposition (PECVD) process, a spin coating process, a high density plasma chemical vapor deposition (HDP-CVD) process, etc.

The carbon-containing layer 120 may be formed to include, e.g., silicon carbide, silicon carbonitride, etc.

An etch stop layer (not shown) including silicon nitride, silicon carbide, silicon carbonitride, etc. may be further formed on the substrate 100.

Referring to FIG. 2, a contact plug 130 may be formed through the carbon-containing layer 120 and the first insulating interlayer 110 to contact the substrate 100.

Particularly, an opening (not shown) may be formed through the first insulating interlayer 110 and the carbon-containing layer 120 to expose a top surface of the substrate 100, and a first conductive layer may be formed on the exposed top surface of the substrate 100 and the carbon-containing layer 120 to sufficiently fill the opening. The first conductive layer may be planarized until a top surface of the carbon-containing layer 120 is exposed to form the contact plug 130. The planarization process may be performed by a chemical mechanical polishing (CMP) process and/or an etch-back process.

The first conductive layer may be formed to include a doped polysilicon, a metal, e.g., titanium, tantalum, tungsten, a metal nitride, e.g., titanium nitride, tantalum nitride, tungsten nitride, etc., or a metal silicide.

In example embodiments, a top surface of the contact plug 130 may be coplanar with the top surface of the carbon-containing layer 120. Alternatively, the top surface of the contact plug 130 may be formed to be lower than that of the carbon-containing layer 120.

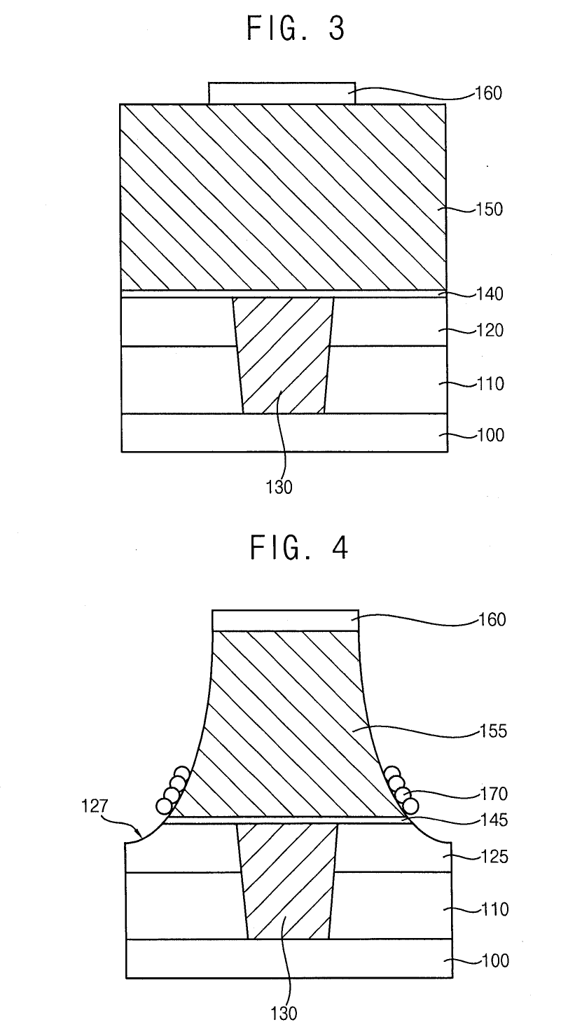

Referring to FIG. 3, a barrier layer 140, a second conductive layer 150 and a mask 160 may be sequentially formed on the contact plug 130 and the carbon-containing layer 120.

For example, the barrier layer 140 may be formed of a metal nitride, e.g., titanium nitride, tantalum nitride, tungsten nitride, etc., and the second conductive layer 150 may be formed of a metal nitride and/or a metal, e.g., aluminum, titanium, tantalum, tungsten, etc.

The mask 160 may include a photoresist pattern. An anti-reflective layer (not shown) may be further formed between the second conductive layer 150 and the mask 160, which may be formed to include silicon nitride, silicon oxynitride, etc.

The mask 160 may be formed to vertically overlap at least a portion of the contact plug 130.

Referring to FIG. 4, the second conductive layer 150 may be etched using the mask 160 as an etching mask to form a wiring 155.

In the etching process, together with the second conductive layer 150, the barrier layer 140 and an upper portion of the carbon-containing layer 130 thereunder may be also etched so that a barrier layer pattern 145 and a carbon-containing layer pattern 125 may be formed. A recess 127 may be formed on a top surface of the carbon-containing layer pattern 125 adjacent to the wiring 155.

In example embodiments, the etching process may be performed by a dry etching process using an etching gas.

In the dry etching process, the upper portion of the carbon-containing layer 120 under the second conductive layer 150 may be etched by the etching gas so that a material including carbon, e.g., a polymer 170 may be formed. The polymer 170 may be formed on a lower sidewall of the wiring 155 so as to serve as a protection layer.

When the second conductive layer 150 has a relatively thick thickness, a polymer may be insufficient in the etching gas, however, the carbon-containing layer 120 may compensate for the insufficiency of polymer in the etching gas. Thus, the polymer 170 generated from the carbon-containing layer 120 may protect a lower portion of the wiring 155 from being over-etched due to the etching gas in the etching process. Therefore, the wiring 155 may be formed to have a smooth sidewall profile without having an undercut.

A lower portion of a wiring 157 (see FIG. 6) in accordance with Comparative Example may be over-etched so that an undercut 159 may be formed therein.

Particularly, referring to FIG. 6, in this example no carbon-containing layer is formed on a first insulating interlayer 110 on a substrate 100, and thus, a polymer for protecting the wiring 157 may be insufficient when a second conductive layer 150 is etched to form the wiring 157. Thus, an under cut 159 may be formed on the lower portion of the wiring 157 when the second conductive layer 150 is etched, and the wiring 157 may not have a smooth sidewall profile. Therefore, a horizontal cross-sectional area of the wiring 157 may be decreased so that a resistance characteristic of the wiring 157 may be degraded.

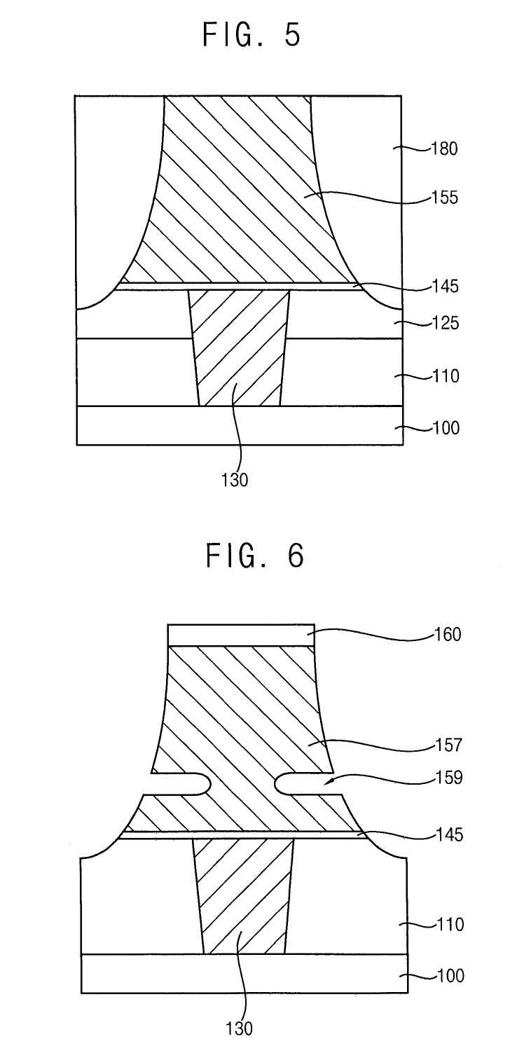

Referring to FIG. 5, a second insulating interlayer 180 may be formed on the carbon-containing layer pattern 125 and the barrier layer pattern 145 to surround the wiring 155 so that the wiring structure may be formed.

The second insulating interlayer 180 may be formed to include an oxide, e.g., silicon oxide.

The wiring structure may be formed to include the contact plug 130 formed on the substrate 100, the carbon-containing layer pattern 125 covering at least a portion of a sidewall of the contact plug 130, e.g., a upper sidewall, and a wiring 155 formed on the contact plug 130 and the carbon-containing layer pattern 125, and the wiring 155 may be electrically connected to the contact plug 130.

The carbon-containing layer pattern 125 may have a flat upper surface under the wiring 155, and the recess 127 may be formed at an upper surface of the carbon-containing layer pattern 125 adjacent to the wiring 155.

The wiring structure may further include the barrier layer pattern 145 between the wiring 155 and the contact plug 130 and the carbon-containing layer pattern 125.

The lower sidewall of the contact plug 130 may be covered by the first insulating interlayer 110 between the substrate 100 and the carbon-containing layer pattern 125.

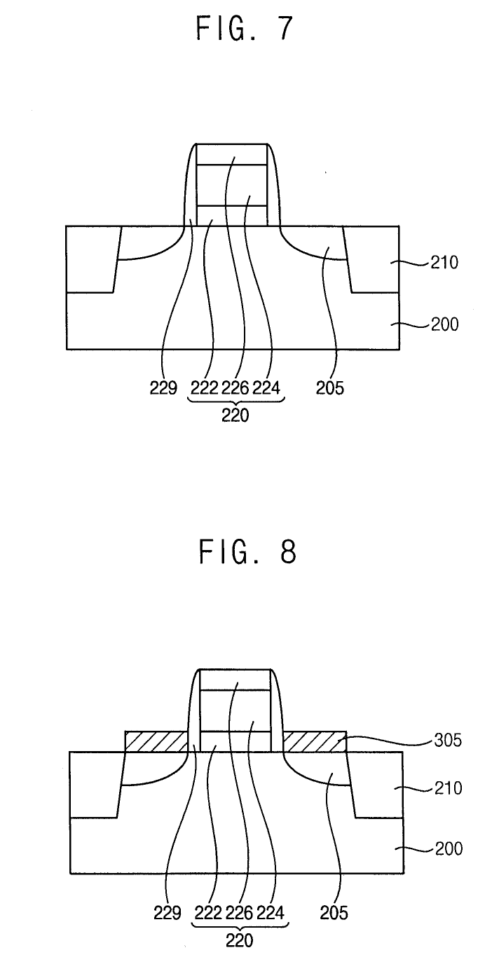

FIGS. 7 to 16 are cross-sectional views illustrating stages of a method of manufacturing a semiconductor device including a wiring structure in accordance with example embodiments. This method may comprise processes substantially the same as or similar to those illustrated with reference to FIGS. 1 to 5. Thus, like reference numerals refer to like elements, and repetitive explanations thereon may be omitted herein.

Referring to FIG. 7, an isolation layer 210 may be formed on a substrate 200, and a gate structure 220 may be formed on the substrate 200.

The substrate 200 may be a semiconductor substrate, e.g., a silicon substrate, and the isolation layer 110 may be formed by a shallow trench isolation (STI) process using an insulating material.

In example embodiments, a gate insulation layer, a gate electrode layer and a gate mask layer may be sequentially formed on the substrate 200, and the gate insulation layer, the gate electrode layer and the gate mask layer may be patterned by a photolithography process. Thus, the gate structure 220 including the gate insulation layer pattern 222, the gate electrode 224 and the gate mask 226 sequentially stacked may be formed. The gate insulation layer may be formed to include, e.g., a metal oxide or silicon oxide, and the gate electrode layer may be formed to include, e.g., doped polysilicon or a metal, and the gate mask layer may be formed to include, e.g., silicon nitride.

A spacer 229 may be formed on a sidewall of the gate structure 220, and an impurity region 205 may be formed at an upper portion of the substrate 200 adjacent to the gate structure 220.

Particularly, a spacer layer may be formed to cover the gate structure 220 on the substrate 200, and the spacer layer may be anisotropically etched to form the spacer 229. The spacer layer may be formed to include, e.g., silicon nitride. An ion implantation process may be performed on the substrate 200 using the gate structure 220 and the spacer 229 as an ion implantation mask to form the impurity region 205. The impurity region 205 may be doped with n-type impurities or p-type impurities.

Referring to FIG. 8, a metal silicide layer 305 may be formed on the impurity region 205.

Particularly, a metal layer may be formed on the impurity region 205, and an annealing process may be performed to form the metal silicide layer 305 on the impurity region 205. A portion of the metal layer that is not reacted with the impurity region 205 may be removed.

The metal layer may be formed to include, e.g., cobalt (Co), platinum (Pt), nickel (Ni), etc.

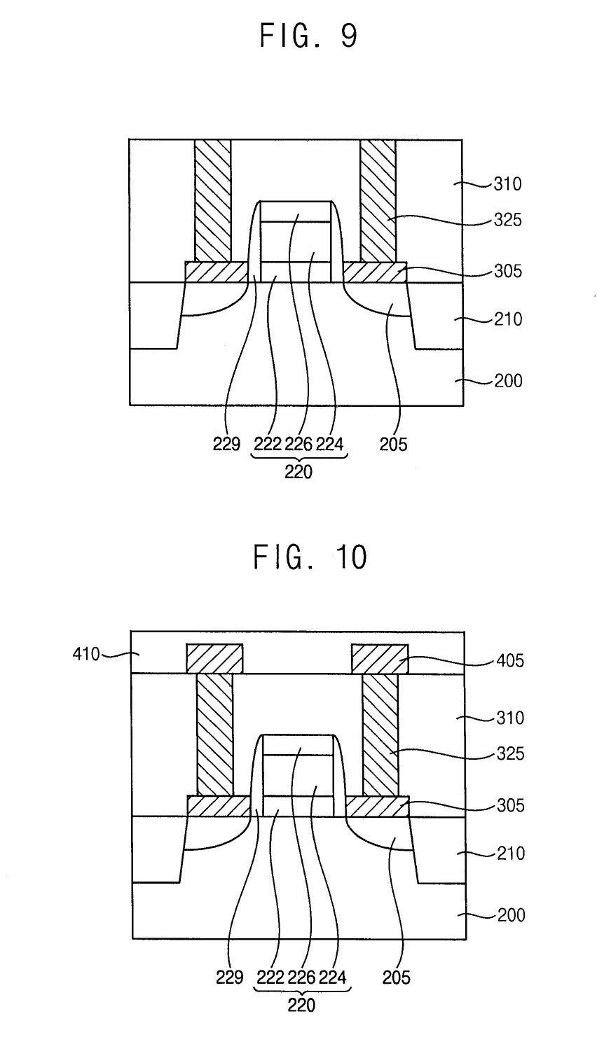

Referring to FIG. 9, a first insulating interlayer 310 may be formed on the substrate 200 on which the gate structure 220, the gate spacer 229, the impurity region 205, the metal silicide layer 305 and the isolation layer 210 are formed, and a first contact plug 325 may be formed through the first insulating interlayer 310 to contact the metal silicide layer 305.

The first insulating interlayer 310 may be formed of an insulating material, e.g., silicon oxide.

The first contact plug 325 may be formed by partially removing the first insulating interlayer 310 to form a first contact hole (not shown) exposing at least a portion of the metal silicide layer 305, forming a first conductive layer on the exposed portion of the metal silicide layer 305 and the first insulating interlayer 310 to sufficiently fill the first contact hole, and planarizing the first conductive layer until a top surface of the first insulating interlayer 310 may be exposed. The first conductive layer may be formed to include, e.g., a doped polysilicon, a metal, a metal nitride, etc. The planarization process may be performed by a chemical mechanical polishing (CMP) process and/or an etch-back process.

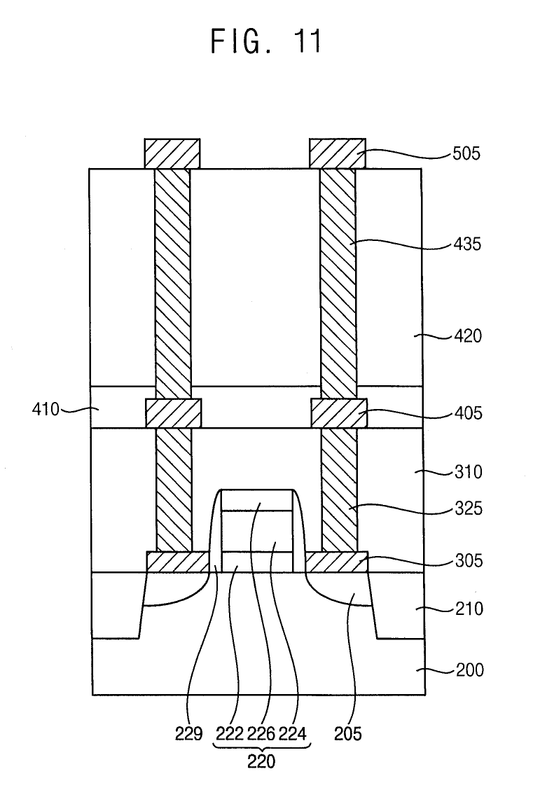

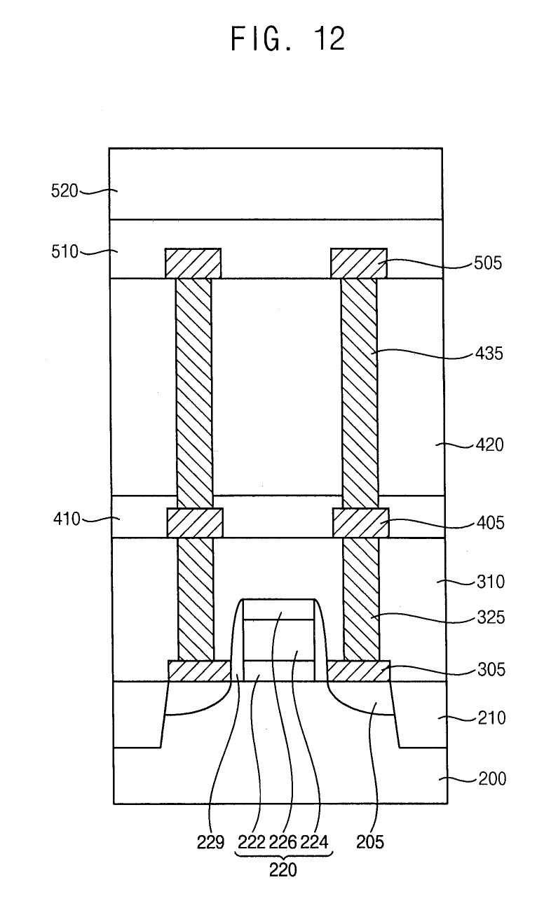

Referring to FIG. 10, a first wiring 405 may be formed to contact a top surface of the first contact plug 325.

That is, the first wiring 405 may be formed on the first insulating interlayer 310 to contact the top surface of the first contact plug 325, and a second insulating interlayer 410 may be formed on the first insulating interlayer 310 to cover the first wiring 405.

The first wiring 405 may be formed to include a metal, e.g., tungsten, aluminum, copper, etc., a metal nitride, or a metal silicide, and the second insulating interlayer 410 may be formed to include an insulating material, e.g., silicon oxide.

Alternatively, the first wiring 405 may be formed by a damascene process. That is, the second insulating interlayer 410 may be formed on the first contact plug 325 and the first insulating interlayer 310, and then, the first wiring 405 may be formed through the second insulating interlayer 410.

In other words, an opening (not shown) may be formed though the second insulating interlayer 410 so that the top surface of the first contact plug 325 may be exposed, and a conductive layer filling the opening may be formed on the exposed top surface of the first contact plug 325 and the second insulating interlayer 410. An upper portion of the conductive layer may be planarized until a top surface of the second insulating interlayer 410 is exposed to form the first wiring 405. The damascene process may be applied to the formation of other wirings that may be illustrated hereinafter.

Referring to FIG. 11, a third insulating interlayer 420 may be formed on the second insulating interlayer 410, and a second contact plug 435 may be formed through the second and third insulating interlayers 410 and 420 to be electrically connected to the first wiring 405. A second wiring 505 may be formed to be electrically connected to the second contact plug 435.

The third insulating interlayer 420 may be formed of an insulating material, e.g., silicon oxide, and the second contact plug 435 and the second wiring 505 may be formed of, e.g., a metal, a metal nitride, a metal silicide, etc.

Referring to FIG. 12, a process substantially the same as or similar to that illustrated with reference to FIG. 1 may be performed.

That is, a fourth insulating interlayer 510 may be formed on the third insulating interlayer 420 to cover the second wiring 505, and a carbon-containing layer 520 may be formed on the fourth insulating interlayer 510.

The fourth insulating interlayer 510 may be formed to include an insulating material, e.g., silicon oxide, and the carbon-containing layer 520 may be formed to include, e.g., silicon carbide, silicon carbonitride, etc.

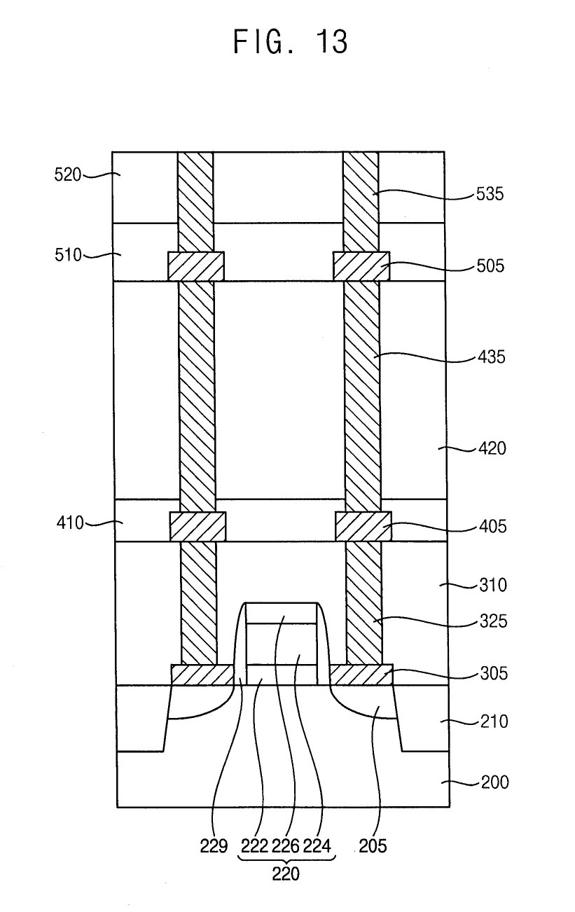

Referring to FIG. 13, a process substantially the same as or similar to that illustrated with reference to FIG. 2 may be performed.

That is, a third contact plug 535 may be formed through the carbon-containing layer 520 and the fourth insulating interlayer 510 to be electrically connected to the second wiring 505.

The third contact plug 535 may be formed of a metal, a metal nitride, and/or a metal silicide, etc.

In example embodiments, a top surface of the third contact plug 535 may be formed to be coplanar with a top surface of the carbon-containing layer 520. Alternatively, the top surface of the third contact plug 535 may be formed to be lower than the top surface of the carbon-containing layer 520.

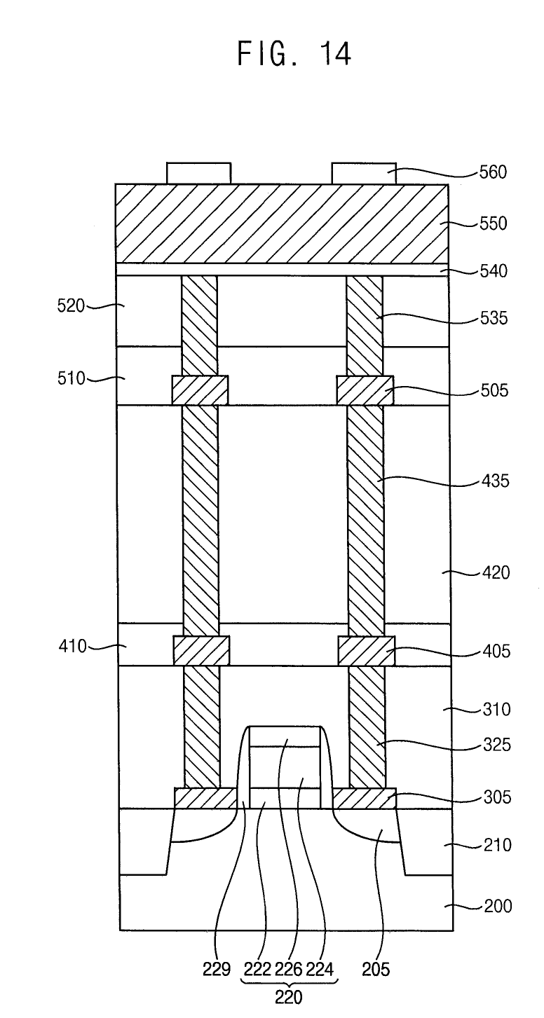

Referring to FIG. 14, a process substantially the same as or similar to that illustrated with reference to FIG. 3 may be performed.

That is, a barrier layer 540, a second conductive layer 550 and a mask 560 may be sequentially formed on the third contact plug 535 and the carbon-containing layer 520.

The barrier layer 540 may be formed of, e.g., a metal nitride, and the second conductive layer 550 may be formed of, e.g., a metal or a metal nitride.

The mask 560 in which a photoresist pattern may be included may be formed to vertically overlap at least a portion of the third contact plug 535

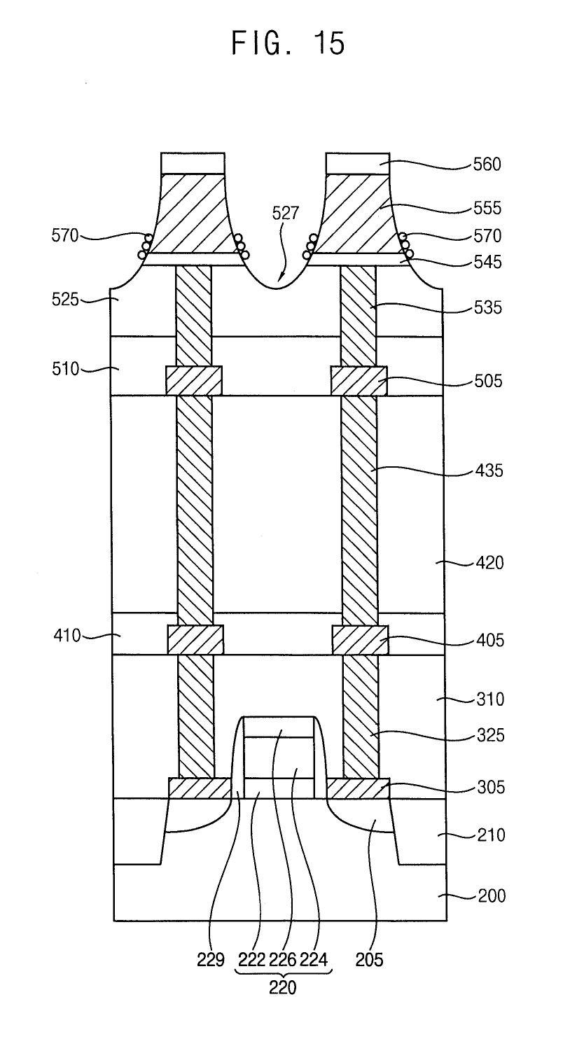

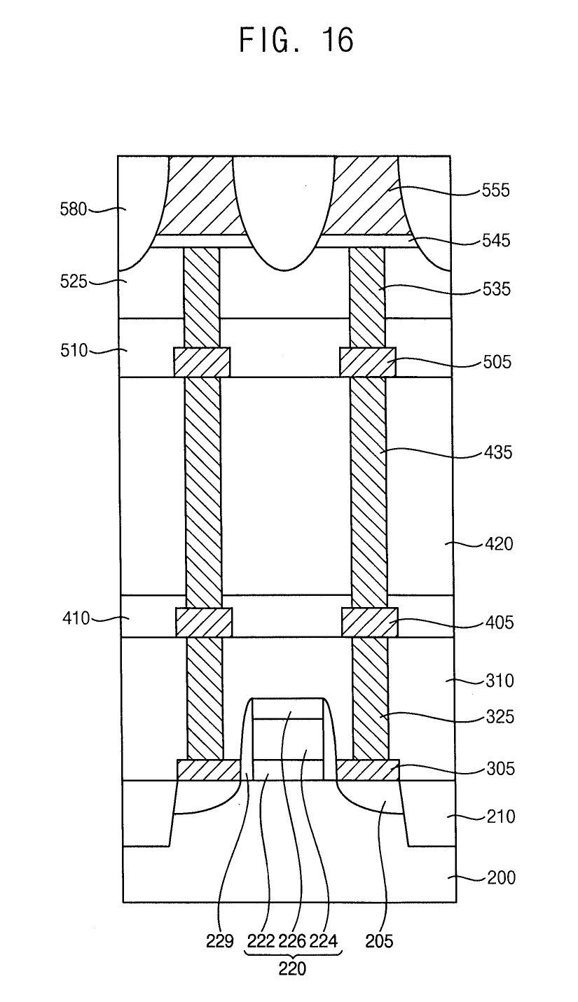

Referring to FIG. 15, a process substantially the same as or similar to that illustrated with reference to FIG. 4 may be performed.

That is, the second conductive layer 550 may be etched using the mask 560 as an etching mask to form a third wiring 555.

In the etching process, together with the second conductive layer 550, the barrier layer 540 and an upper portion of the carbon-containing layer 520 thereunder may be also etched so that a barrier layer pattern 545 and a carbon-containing layer pattern 525 may be formed, respectively. A recess 527 may be formed on a top surface of the carbon-containing layer pattern 525 adjacent to the third wiring 555.

In example embodiments, the etching process may be performed by a dry etching process using an etching gas. In the dry etching process, the upper portion of the carbon-containing layer 520 under the second conductive layer 550 may be etched by the etching gas so that a material including carbon, e.g., a polymer 570 may be formed. The polymer 570 may be formed on a lower sidewall of the wiring 555 so as to serve as a protection layer.

When the second conductive layer 550 has a relatively thick thickness, polymer may be insufficient in the etching gas, however, the carbon-containing layer 520 may compensate for the insufficiency of polymer in the etching gas. Thus, the polymer 570 generated from the carbon-containing layer 520 may protect a lower portion of the wiring 555 from being over-etched due to the etching gas in the etching process. Therefore, the wiring 555 may be formed to have a smooth sidewall profile substantially without the presence of an undercut.

Referring to FIG. 16, a process substantially the same as or similar to that illustrated with reference to FIG. 5 may be performed.

That is, a fifth insulating interlayer 580 may be formed on the carbon-containing layer pattern 525 and the barrier layer pattern 545 to surround the third wiring 555 so that the semiconductor device including the wiring structure may be manufactured. The fifth insulating interlayer 580 may be formed to include an oxide, e.g., silicon oxide.

The method of forming a wiring structure may be used for manufacturing various types of semiconductor devices. For example, the method may be applied to the formation of, e.g., NAND flash memory devices, NOR flash memory devices, dynamic random access memory (DRAM) devices, static random access memory (SRAM) devices logic devices, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a wiring structure, comprising:
forming a carbon-containing layer on a substrate;
forming a conductive layer on the carbon-containing layer; and
etching the conductive layer and an upper portion of the carbon-containing layer to form a wiring and a carbon-containing layer pattern, respectively.

2. The method of claim 1, wherein etching the conductive layer and the upper portion of the carbon-containing layer includes forming a polymer on a lower sidewall of the wiring from carbon in the carbon-containing layer.

3. The method of claim 1, wherein the carbon-containing layer includes silicon carbide or silicon carbonitride.

4. The method of claim 1, wherein prior to forming the carbon-containing layer, further comprising:
forming an insulating interlayer on the substrate; and
forming a contact plug through the carbon-containing layer and the insulating interlayer.

5. The method of claim 4, wherein the conductive layer is formed on the carbon-containing layer and the contact plug, and the wiring is formed on the contact plug.

6. The method of claim 1, wherein prior to forming the conductive layer, further comprising forming a barrier layer on the carbon-containing layer.

7. The method of claim 1, wherein the conductive layer is formed of a metal nitride and/or a metal comprising aluminum, titanium, tantalum, or tungsten.

8. The method of claim 1, wherein etching the conductive layer and the upper portion of the carbon-containing layer includes performing a dry etching process.

9. A wiring structure, comprising:
a contact plug on a substrate;
a carbon-containing layer pattern surrounding at least a portion of a sidewall of the contact plug; and
a wiring on the contact plug and the carbon-containing layer pattern, the wiring being electrically connected to the contact plug.

10. The wiring structure of claim 9, wherein the carbon-containing layer pattern has a flat upper surface under the wiring, and a recess is formed on an upper surface of the carbon-containing layer pattern adjacent to the wiring.

11. The wiring structure of claim 9, further comprising a barrier layer pattern between the wiring and the contact plug and the carbon-containing layer pattern.

12. The wiring structure of claim 11, further comprising:
an insulating interlayer between the substrate and the carbon-containing layer pattern,
and wherein the insulating interlayer surrounds a lower sidewall of the contact plug.

13. The wiring structure of claim 9, wherein the wiring has a smooth sidewall profile.

14. The wiring structure of claim 9, wherein the wiring includes a metal nitride and/or a metal comprising aluminum, titanium, tantalum, or tungsten.

15. The wiring structure of claim 9, wherein the carbon-containing layer pattern includes silicon carbide or silicon carbonitride.

16. A method of manufacturing a semiconductor device, the method comprising:
forming a gate structure on a substrate;
forming an impurity region at an upper portion of the substrate adjacent to the gate structure;
forming an insulating interlayer on the substrate to cover the gate structure;
forming a carbon-containing layer on the insulating interlayer;
forming a contact plug through the carbon-containing layer and the insulating interlayer to be electrically connected to the impurity region;
forming a conductive layer on the contact plug and the carbon-containing layer; and
etching the conductive layer and an upper portion of the carbon-containing layer to form a wiring and a carbon-containing layer pattern, respectively.

17. The method of claim 16, wherein etching the conductive layer and the upper portion of the carbon-containing layer includes forming a polymer on a lower sidewall of the wiring from carbon in the carbon-containing layer.

18. The method of claim 16, wherein the carbon-containing layer includes silicon carbide or silicon carbonitride.

19. The method of claim 16, wherein the wiring is formed on the contact plug.

20. The method of claim 16, wherein prior to forming the conductive layer, further comprising forming a barrier layer on the carbon-containing layer.
